(19) United States
(12) Patent Application Publication
(10) Pub. No.: US 2011/0174958 A1
(43) Pub. Date: Jul. 21, 2011

(54) PHOTOSENSITIVE SENSOR CELL, DETECTOR UNIT, AND IMAGING MEANS

(75) Inventors: Cornelis Francois Christiaan Weststrate, Krabbendijke (NL); Barend Marius Ter Haar Romenij, S-Hertogenbosch (NL)

(73) Assignee: Technische Universiteit Eindhoven, Eindhoven (NL)

(21) Appl. No.: 12/999,090

(22) PCT Filed: Jun. 18, 2009
(86) PCT No.: PCT/NL2009/000132

§ 371 Date: Apr. 7, 2011

(30) Foreign Application Priority Data
Jun. 19, 2008 (NL) 1035604

(51) Int. Cl. H01L 27/146; H01L 31/0352

(52) U.S. Cl. 250/208.1; 250/200

(57) ABSTRACT

A photosensitive sensor cell includes a photosensitive element with a detection surface for receiving light. The element is manufactured from a material of which at least one electrically measurable quantity is changeable under the influence of light. The element further includes electrodes for making the quantity measurable such that a property of the light can be determined. The element has a pointed shape, which renders a robust decorrelation possible so as to obtain super-resolution.

The present invention relates to a photosensitive sensor cell comprising a photosensitive element with a detection surface for receiving light, which element is manufactured from a material in which at least one electrically measurable quantity is changeable under the influence of light, and further comprising electrodes for rendering said quantity measurable such that a property of the light can be determined.

The present invention further relates to a photosensitive detector unit and to imaging means in which the above photosensitive sensor cell is applied.

A photosensitive sensor cell as described above is generally known and is used, for example, in charge coupled devices (CCDs) CCD is a widely used and known technology which converts electromagnetic radiation into an electric charge, thus rendering it possible to measure and process electromagnetic radiation electrically. CCDs are used in particular in the field of image capturing, such as in cameras, but CCDs may also be used for registering electromagnetic radiation. CCD was invented in 1970 and its original application was information storage, for example as described in U.S. Pat. No. 3,858,232 (Willard S. Boyle et al.).

A CCD chip consists of semiconductor material in which potential wells are formed by incident photons. These potential wells can be transported by means of voltage differences to a measuring device of the CCD, which is capable of reading out and storing the location-dependent information. It is possible in this manner to register the location-dependent light intensity by means of a CCD. When in addition a colour filter is used, a CCD can be obtained for registering in multicoloured light. So-termed Bayer filters are often used for this, which consist of a specific pattern of red, green, and blue filters that cover the surface of a CCD.

A CCD sensor cell substantially comprises an optically active layer of semiconductor material. The compact arrangement of sensor cells on the surface of a CCD in conjunction with the scattering of light has the effect that the information values of adjoining cells on the CCD surface are mutually correlated to a certain degree. This means that the information from a CCD is to be decorrelated in order to obtain a sharp image. The decorrelation or sharpening of the image (“deblurring”) takes place by means of a Fourier transformation of the information obtained from the CCD chip. The received signal is divided by the Fourier transform of the aperture function in the Fourier domain. Said aperture function is given by the shape of the sensor cell and the interspacings of the sensor cells. The decorrelation of the CCD signal is limited by the fact that the aperture function contains zeros in the Fourier domain, so that dividing by the Fourier transform of the aperture function is possible only partly.

The paper entitled “Pyramid-shaped silicon photo detector with sub-wavelength aperture” presented in IEEE Transactions on Electron Devices, vol. 49, no. 6, June 2002 by Chelly et al. discloses a photosensitive sensor cell of the sub-wavelength type (i.e. whose dimensions are smaller than the wavelength of the light) for use in optical applications for the near field. Such a technology is not meant for, neither is it suitable for use in optical applications such as, for example, image registration. Furthermore, the processing of information from such sensors is based on a principle that is entirely different from that of the processing of image signals from, for example, a CCD device.

It is an object of the present invention to obviate the problem outlined above and to provide a photosensitive sensor cell that has a high motional stability. Itis a further object of the invention to provide a photosensitive sensor cell that can be used in a photosensitive detector unit comprising a comparatively small number of sensor cells and yet capable of generating a sharp image.

The above objects are achieved according to the invention in that it provides a photosensitive sensor cell comprising a photosensitive element with a detection surface for receiving light, which element is manufactured from a material of which at least one electrically measurable quantity is changeable under the influence of light, and further comprising electrodes for rendering said quantity measurable such that a property of the light can be determined, characterized in that said photosensitive element is point-shaped.

The fact that the photosensitive sensor cell is provided with photosensitive elements having a pointed shape means that said cell has an aperture function whose Fourier transform has no zero points in the Fourier domain. The Fourier transform of the aperture function goes asymptotically to zero in the Fourier domain without any zero passages, so that the decorrelation in the frequency domain of the sensor cells is not limited by the aperture function.

The term “point-shaped” here denotes that the photosensitive element has a three-dimensional shape such that it comprises both a detection surface and a pointed end. This may relate to, for example, a conical or pyramidal shape. Obviously, there are alternative and asymmetrical shapes conceivable which have the above properties. The advantage of this shape is that the incident light enters at the detection surface, which has the greatest aperture, and that the sensor cell may be regarded as a stack of detectors of ever decreasing size. The aperture function of a sensor cell with a photosensitive element of this shape is continuously positive in the Fourier domain and has no zero values.

The use of a sensor cell according to the present invention thus renders decorrelation possible throughout the entire frequency domain without said decorrelation in the frequency domain being limited as a result of divisions by zero values. This improvement with respect to prior art photosensitive cells makes a strongly improved image quality available when a sensor cell according to the invention is used. Furthermore, a photosensitive sensor cell according to the invention has a high motional stability because every motional blur can be effectively resolved by decorrelation so as to obtain a sharp image. It is noted in this connection that motional blur causes a high degree of correlation between adjoining points because the movement of, for example, the photosensitive sensor cell causes light that ought to be incident on a certain photosensitive element now to be incident on an adjoining photosensitive element, or on a photosensitive element at a limited distance from the envisaged element. Measured values coming from adjoining elements are accordingly mutually correlated.

In a photosensitive sensor cell according to the state of the art, such as a regular CCD, decorrelation is possible only in part of the frequency domain owing to the restriction imposed by the zero passages of the Fourier transform of the aperture or apodization function in the Fourier domain. The frequency domain in which decorrelation is possible for a prior art photosensitive sensor cell is limited by the zero points of the apodization function, which are located comparatively close to the peak values of the apodization function. Decorrelation is accordingly possible in a limited frequency range only. When a photosensitive sensor cell according to the invention is used, whose aperture or apodization function has no zero passages in the frequency domain, decorrelation can be performed over the entire frequency domain, whereby a considerable improvement in the image quality is obtained and motional blur can be eliminated to a high degree.

It is noted in view of the above that the point-shaped photosensitive element has many points of similarity with the cone-shaped receptor in the retina of the eye. The retina consists of many millions of receptors (around 130 million receptors in the human eye). The major portion of the receptors is formed by rods, i.e. rod-shaped receptors used for seeing under conditions when there is very little light available. These rod-shaped receptors are incapable of distinguishing colours and are least sensitive to red light. Hence red objects often seem to be black in the dark. Furthermore, the rods are bad at seeing sharply (low visual acuity).

A small portion of these receptors, about 5%, is formed by the cone-shaped receptors. These cone-shaped receptors are used for seeing under normal conditions, under daylight and artificial light. The number of cone-shaped receptors in a human eye is estimated at about 4 million. When we compare this with CCD-type imaging means, a CCD camera with 4 million photosensitive elements will be able to provide an image with a resolution of approximately 4 megapixels. This is a comparatively mediocre quality compared with the image quality that can be obtained with a healthy eye. A human eye is capable of providing images with a much higher resolution: a healthy eye can distinguish very small objects with razor sharpness.

It is found that the eye can do this because the eye muscle ensures that the eye continuously scans the object by means of very small movements of short duration, the so-termed microsaccades, which are exactly the same for both eyes. The eye thus of itself performs a movement which under normal circumstances would cause motional blur or unsharpness in a regular CCD. Apparently the eye is capable of eliminating this motional unsharpness and even of providing a much higher resolution as a result of these microsaccades than one would expect on the basis of the number of receptors on the retina.

In a sensor cell according to the invention, the photosensitive element has a shape such that the apodization function or aperture function is continuously positive when transformed into the Fourier domain, i.e. without zero points, so the explanation for the high image quality of the human eye would seem to lie in the degree to which the eye is capable of decorrelating the image over the entire frequency domain, whereby a high degree of sharpness and a high resolution can be obtained with only a limited number of receptors. The inventors have recognized that the use of the photosensitive sensor cell according to the present invention may be accompanied by the performance of artificial eye saccades for obtaining an image with a high resolution. This principle will be explained in more detail further below in the description.

According to an embodiment of the present invention, the detection surface of the photosensitive sensor cell constitutes a geometric base of the point-shaped photosensitive element. According to a further embodiment, the photosensitive element furthermore comprises a point-shaped end that is located opposite the detection surface. According to a yet further embodiment, a side of the photosensitive element, which side is located between the detection surface and the point-shaped end, encloses a constant orientation angle with the detection surface, so as to achieve, for example, a cone or pyramid shape. In an alternative embodiment, however, the orientation angle between the detection surface and a side of the photosensitive element located between the detection surface and the point-shaped end decreases, viewed in a direction from the detection surface to the point-shaped end. This gives the side of the photosensitive cell a convex shape. According to yet another embodiment of the invention, the orientation angle between the detection surface and a side of the photosensitive element located between the detection surface and the point-shaped end increases, viewed in a direction from the detection surface to the point-shaped end. This by contrast leads to a concave shape, so that the photosensitive element becomes bullet-shaped.

The shapes suggested above can provide apodization or aperture functions that offer advantages as regards decorrelation in the frequency domain. This may relate, for example, to a certain degree of sensitivity to given frequency ranges.

In a photosensitive sensor cell according to the invention, the detection surface may have an embodiment with a shape that is chosen from a group comprising round, oval, triangular, rectangular, square, pentagonal, hexagonal, heptagonal, octagonal, polygonal with n angles, where n is a natural number >8, and asymmetrical two-dimensional shapes.

According to an embodiment, the sensor cell is manufactured from a material that is at least partly light-transmitting. The presence of a certain degree of light transmission means that the incident light can effectively reach the subjacent layers of the semiconductor material of the photosensitive element.

As was noted above, the sensor cell may be formed by a plurality of planar photosensitive sub-elements whose cross-sections are decreasing so as to form the point-shaped photosensitive element. This, however, is not an absolute condition, the photosensitive element may alternatively be integrally formed from one piece.

According to a second aspect, the invention provides a photosensitive detector unit comprising a photosensitive sensor cell as described above.

According to a third aspect, the invention provides imaging means comprising a photosensitive sensor cell according to the first aspect as described above or a photosensitive detector unit according to the second aspect as described above.

The imaging means as mentioned above may further comprise means for causing relative movements of the at least one photosensitive sensor cell relative to a surroundings. It can be achieved thereby that the imaging means are capable of causing the photosensitive sensor cell to perform artificial eye saccades, so that with comparatively few photosensitive elements nevertheless a very sharp image with a high resolution can be obtained, as in the naturally shaped eye. This can be achieved in that afterwards decorrelation is applied in an efficient manner, wherein image information received during the performance of the artificial eye saccades with the photosensitive sensor cell can be ascribed to virtual pixel elements which are not actually present, but which are imagined to be present interposed between the actually present pixel elements. This enhances the advantages in more than one respect. The most obvious advantage is the comparatively small number of photosensitive elements in the sensor cell, so that a comparatively small memory capacity is required for storing an image. Another advantage is that the small number of photosensitive elements actually present on the sensor cell means that the imaging means can be manufactured to a much smaller size than if a conventional CCD were used. In space travel applications, a sensor cell or detector unit of regular dimensions can now provide a much higher resolution, so that objects can be made visible that cannot be observed by conventional photosensitive units such as a conventional CCD. The price to be paid for this is that a plurality of images is to be made with mutual sub-pixel shifts.

The invention will be explained in more detail below with reference to a few embodiments thereof, which are not to be regarded as limiting the invention, and to the accompanying drawings, in which:

FIG. 1 diagrammatically depicts a photosensitive sensor cell according to the present invention;

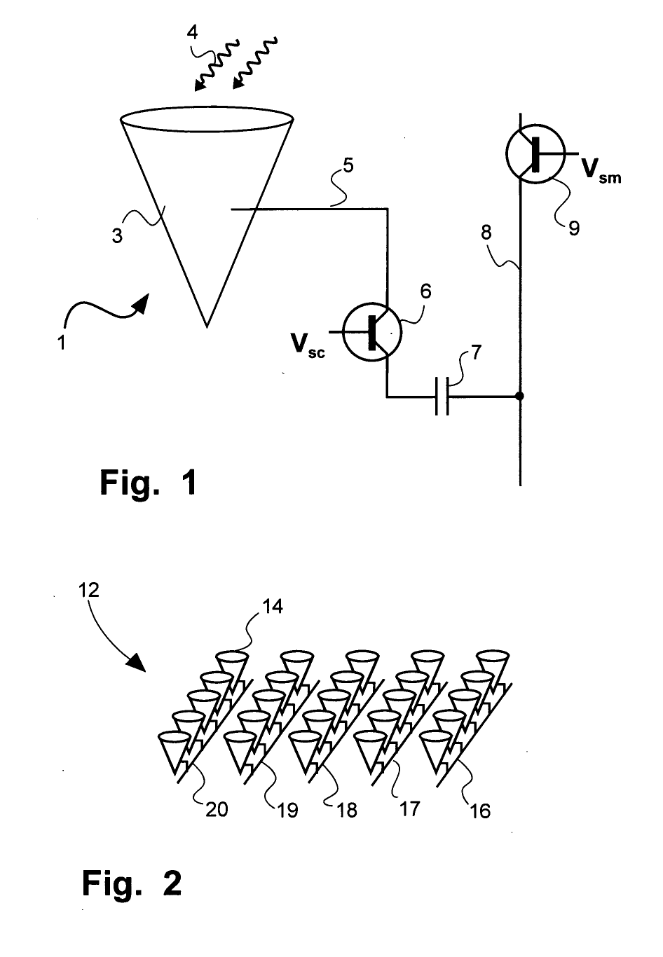

FIG. 2 diagrammatically depicts a group or matrix of photosensitive sensor cells according to the present invention;

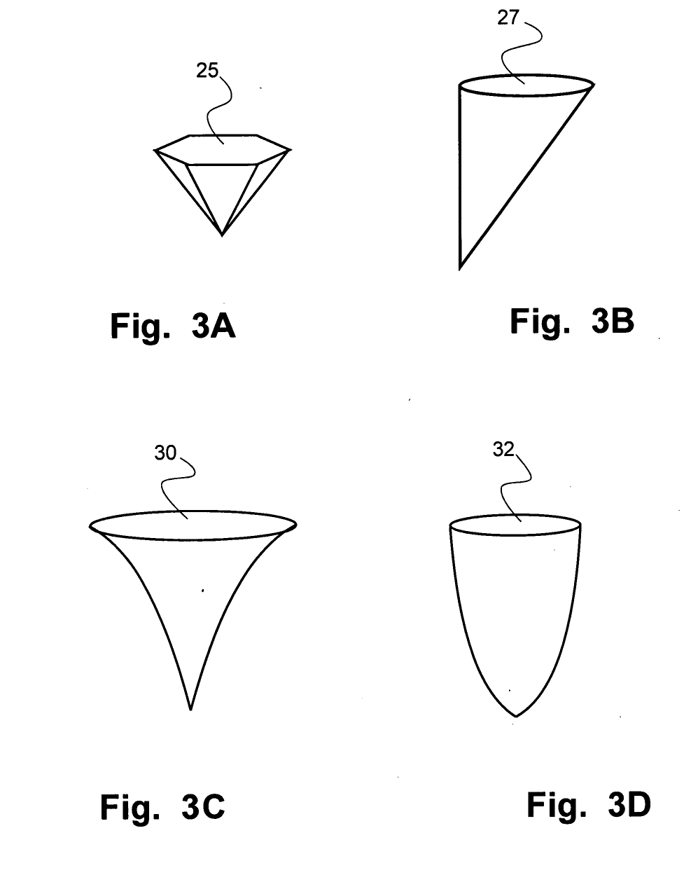

FIGS. 3A-3D show various embodiments of a photosensitive element in a photosensitive sensor cell according to the present invention;

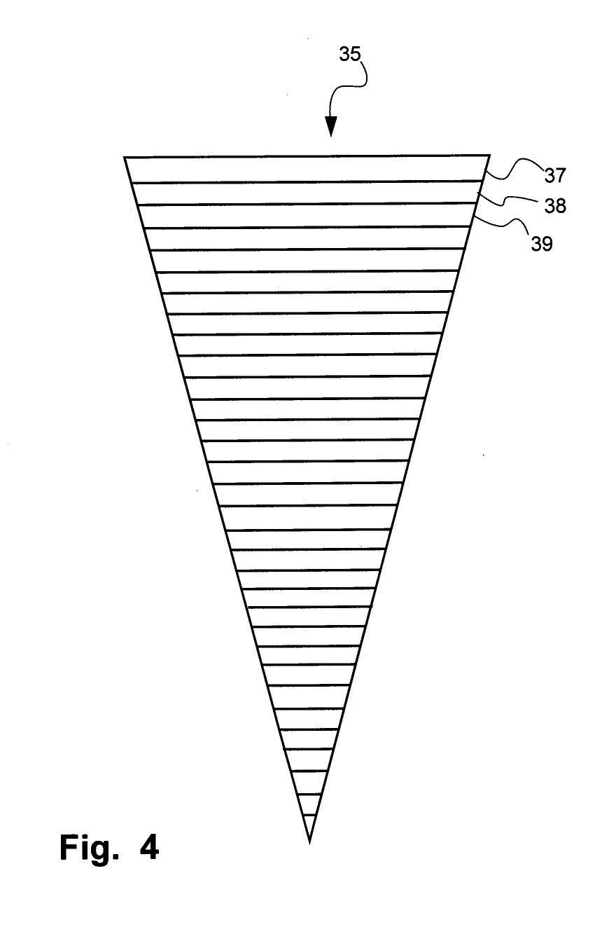

FIG. 4 is a cross-sectional view of a photosensitive element in a photosensitive sensor cell according to the present invention;

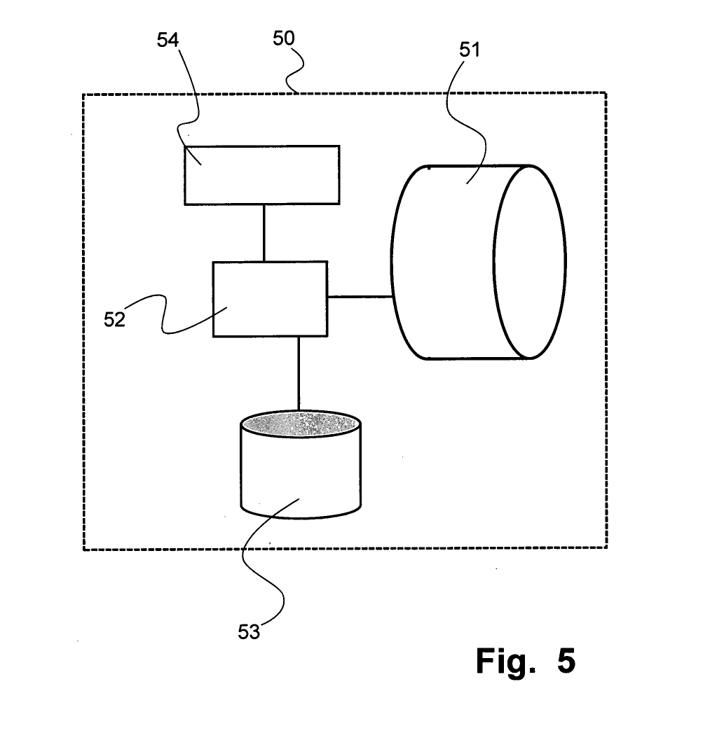

FIG. 5 diagrammatically depicts imaging means according to the present invention;

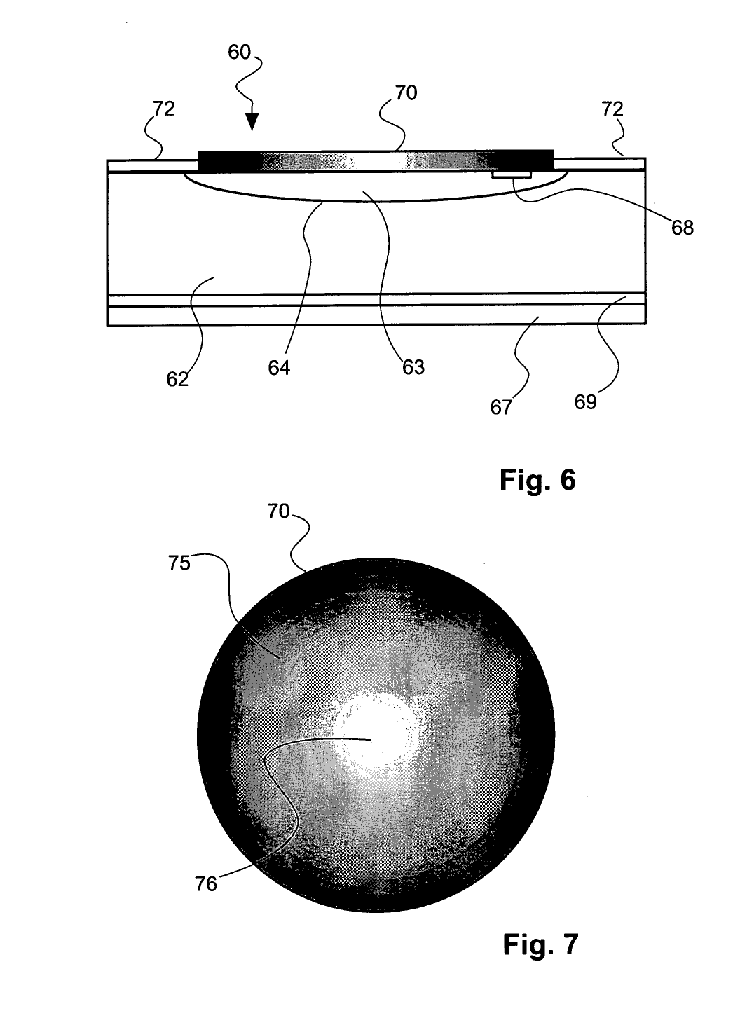

FIG. 6 shows a further embodiment of the invention; and

FIG. 7 shows a mask for use in am embodiment as shown in FIG. 6.

FIG. 1 diagrammatically shows a photosensitive sensor cell 1 according to the present invention. The photosensitive sensor cell 1 comprises a photosensitive element 3 of conical design. Photons can be incident on the detection surface 2 of the photosensitive element 3. These photons will be converted into, for example, electron-hole pairs in the material of the photosensitive element 3, so that a build-up of charge takes place in the photosensitive element 3. The photosensitive element 3 can be read out via an output 5 by means of a switching transistor 6. The switching transistor 6 is opened in that a suitable voltage Vfc is applied to the base of the transistor 6. Opening of the transistor 6 will cause the charge of the photosensitive element 3 to flow into a storage capacitor 7. Said storage capacitor 7 can subsequently be read out in that a transistor 9 is opened through application of a suitable voltage Vsm across the base of this transistor. The photosensitive sensor 1 cell may form part of a group of sensor cells, such as a photosensitive matrix (an example of which is shown in FIG. 2). If this is the case and the photosensitive matrix is part of, for example, a photo camera, a photo can be taken by means of the transistor 6 and all similar transistors of further sensor cells of the group being simultaneously opened, so that the charge of each and every photosensitive element of the group is drained off and is stored in the respective storage capacitor 7. When all storage capacitors 7 are sequentially read out through opening of the associated transistors (for example transistor 9), the image can be digitally read out. Those skilled in the art will understand that the principle of charge coupling may equally well be applied here, as is usual in CCDs according to the prior art.

FIG. 2 shows a group 12 of photosensitive sensor cells such as the sensor cell 14. The sensor cells in each column may be connected, for example, to a single transport line (16, 17, 18, 19, or 20), which renders it possible to read out these cells one by one. FIGS. 1 and 2 are based on a conical design of the photosensitive sensor cell.

FIGS. 3A to 3D show a few alternative embodiments in which the photosensitive element is shaped as a pyramid with a hexagonal base 25 (FIG. 3A), an asymmetrical cone 27 (FIG. 3B), a semi-hyperboloidal pointed element 30 with concave sides (FIG. 3C), and a bullet-shaped photosensitive element 32 with convex sides (FIG. 3D). The invention is obviously not limited to these embodiments; other point-shaped designs may also offer the advantages of the present invention.

FIG. 4 is a cross-sectional view of an embodiment of a photosensitive element according to the present invention. A photosensitive element 35 consists of a rod comprising photosensitive layers 37 which together form the three-dimensional point-shaped photosensitive element. The photosensitive sub-elements, such as the sub-elements 37, 38, and 39, may each form, for example, a p-n junction in which electron-hole packets are formed under the influence of incident photons. The degree of optical attenuation of each of the layers, such as the layers 37, 38, 39, and all other layers of the photosensitive element, is such that the light incident on the photosensitive element 35 is preferably partly transmitted by the layers, so that all layers of the photosensitive element can receive part of the signal. The individual layers of the photosensitive element may be read out simultaneously, if so desired, it is not necessary to read out the layers sequentially one by one.

FIG. 5 shows imaging means 50 according to the present invention. The imaging means are provided with a detector unit 51 that comprises a plurality of sensor cells (not visible) such as, for example, the sensor cell 1 of FIG. 1. The detector unit 50 is connected to processing means 52 which store the information resulting from a read-out of the detector unit in a storage unit 53. The imaging means further comprise motion means 54 which are capable of causing the detector unit 51 of the imaging means to move such that saccadic eye movements can be simulated. The processing unit 52 is designed to perform decorrelation by means of a suitable apodization function which is stored, for example, in the storage means 53.

The invention described above is based in particular on a suitable choice of the shape of the photosensitive element such that the aperture function of the photosensitive element in the Fourier domain is continuously positive and has no zero values. As a result of this, decorrelation is possible over the entire frequency domain. A closer study of the operation of the photosensitive sensor cell according to the invention and of the relation between the three-dimensional shape of the photosensitive sensor cell on the one hand and the aperture function thereof on the other hand has led to the conclusion that the location-dependent photosensitivity on the detection surface is relevant to the shape of the aperture function in the Fourier domain. The pointed shape of the photosensitive sensor cell (for example of a conical sensor cell) ensures that the sensor cell does not have the same photosensitivity everywhere on the detection surface. The point on the detection surface situated immediately opposite the pointed end, for example, is much more photosensitive than the edges of the detection surface, where there is comparatively little semiconductor material present.

Research has shown that the advantages of the invention can be obtained to a certain degree also in that a photosensitive sensor cell or photodiode as known from the prior art is provided with a mask of which the light transmission varies over the surface. The degree of light transmission or transmission coefficient of the mask varies such that there is a location on the mask where the light is fully transmitted by the mask, and the light transmission decreases in proportion as the distance to this location increases. An example of this is given in FIG. 6.

FIG. 6 shows a combination 60 of a photosensitive sensor cell and a mask. The photosensitive sensor cell consists of an n-type semiconductor layer 62 provided with a p-type semiconductor layer 63. The p-type semiconductor material 63 is present on the side of the optical element on which light can be incident. The edges of the photosensitive side of the photosensitive sensor cell are covered by diffraction filters 72. On or in the p-type semiconductor material there is an anode 68, and under the n-type semiconductor material 62 there is a cathode 67. A layer of semiconductor material of the n+ type 69 is present between the n-type semiconductor material 62 and the cathode 67. The special feature of this photosensitive sensor cell is that it is provided with a mask 70 whose light transmission at the edges is (very) low or even nil and whose light transmission in the centre of the mask is (very) high. The photosensitivity of the mask shown in this embodiment has a centrically symmetric surface gradient such that it transmits most light in the centre and least light at the edges.

FIG. 7 is a plan view of the mask 70 of the photosensitive sensor cell 60 of FIG. 6. The centre 76 has a high transmission coefficient; i.e. it transmits much light. The transmission coefficient decreases over the surface 75 in the direction towards the edges and is a minimum at the edges of the mask.

A mask as shown in FIGS. 6 and 7 is the optical equivalent, as far as the aperture function is concerned, of a conical photosensitive sensor cell according to the invention. The advantages of the invention can thus be obtained to a certain extent thereby when a mask as shown in FIGS. 6 and 7 is used.

Generally speaking, the advantages of the present invention can be obtained in that a photosensitive sensor cell is provided with a non-uniform sensitivity profile wherein said sensitivity profile (which is location-dependent over the surface) is such that it has a local maximum and decreases with an increasing distance to the location of this maximum. Such a non-uniform sensitivity profile provides an optical equivalent of a point-shaped photosensitive sensor cell. The non-uniform sensitivity profile may be obtained, as described above, by means of a mask whose translucence or optical transmission coefficient is not uniform over its surface.

It will be apparent to those skilled in the art from the above description that the invention relates to image registration. The invention is not limited to the embodiments disclosed above, but exclusively by the scope of protection of the appended claims.

1. A photosensitive sensor cell comprising a photosensitive element with a detection surface for receiving light, which element is manufactured from a material in which at least one electrically measurable quantity is changeable under the influence of light, and further comprising electrodes for rendering the quantity measurable such that a property of the light can be determined, characterized in that said photosensitive element is point-shaped.

2. A photosensitive sensor cell of claim 1, wherein the detection surface constitutes a geometric base of the point-shaped photosensitive element.

3. A photosensitive sensor cell of claim 2, wherein the photosensitive element further comprises a point-shaped end that is located opposite the detection surface.

4. A photosensitive sensor cell of claim 3, wherein a side of the photosensitive element located between the detection surface and the point-shaped end thereof encloses a constant orientation angle with the detection surface so as to provide a conical shape.

5. A photosensitive sensor cell of claim 3, wherein an orientation angle between the detection surface and a side of the photosensitive element located between the detection surface and the point-shaped end thereof decreases, viewed in a direction from the detection surface to the point-shaped end, so as to provide a convex shape.

6. A photosensitive sensor cell of claim 3, wherein an orientation angle between the detection surface and a side of the photosensitive element located between the detection surface and the point-shaped end thereof increases, viewed in a direction from the detection surface to the point-shaped end, so as to provide a concave shape.

7. A photosensitive sensor cell of claim 1, wherein the detection surface has a shape that is chosen from a group comprising round, oval, triangular, rectangular, square, pentagonal, hexagonal, heptagonal, octagonal, polygonal with n angles, where n is a natural number and n>8, and asymmetrical two-dimensional shapes.

8. A photosensitive sensor cell of claim 1, wherein the sensor cell is manufactured from a material that is at least partly light-transmitting.

9. A photosensitive sensor cell of claim 1, wherein the sensor cell comprises a plurality of planar photosensitive sub-elements whose the cross-sections are decreasing so as to form the point-shaped photosensitive element.

10. A photosensitive detector unit comprising a photosensitive sensor cell of claim 1.

11. Imaging means comprising at least one photosensitive sensor cell of claim 1.

12. Imaging means of claim 11, further comprising means for causing relative movements of the at least one photosensitive sensor cell or photosensitive detector unit relative to a surroundings.

13. Imaging means of claim 12, wherein the means for causing relative movements of the at least one photosensitive sensor cell or photosensitive detector unit are designed for providing movements over distances smaller than the diameter of a single sensor cell.

14. Imaging means of claim 12, wherein the means for causing relative movements of the at least one photosensitive sensor cell or photosensitive detector unit are designed for providing movements with a motional frequency of more than 10 movements per second.

15. Imaging means of claim 13, wherein the means for causing relative movements of the at least one photosensitive sensor cell or photosensitive detector unit are designed for providing movements with a motional frequency of more than 10 movements per second.

16. Imaging means comprising a photosensitive detector unit according to claim 10.
